(19) United States
(12) Patent Application Publication
(10) Pub. No.: US 2013/0019935 A1
(43) Pub. Date: Jan. 24, 2013

(54) SOLAR CELL MODULE AND METHOD FOR MANUFACTURING THE SAME

(71) Applicant: Dong-Jin Kim, Yongin-si (KR)

(72) Inventor: Dong-Jin Kim, Yongin-si (KR)

(21) Appl. No.: 13/433,251

(22) Filed: Mar. 28, 2012

(30) Foreign Application Priority Data
Jul. 21, 2011 (KR) 10-2011-0072626

(51) Int. Cl. H01L 31/0224; H01L 31/18

(52) U.S. Cl. 136/256; 438/98; 257/E31.124

(57) ABSTRACT

A manufacturing method of a solar cell module according to an exemplary embodiment of the present invention includes: forming a first electrode on a transparent substrate; forming a first groove at the first electrode by performing a first laser scribing process; forming a semiconductor layer on the first electrode; forming a second groove at the semiconductor layer by performing a second laser scribing process; forming a second electrode on the semiconductor layer; forming a third groove at the semiconductor layer and the second electrode by performing a third laser scribing process; and forming fourth and fifth grooves at the semiconductor layer and the second electrode by performing a fourth laser scribing process. The fourth laser scribing process includes using first and second laser beams.

### CROSS-REFERENCE TO RELATED APPLICATION

This application claims priority to and the benefit of Korean Patent Application No. 10-2011-0072626 filed in the Korean Intellectual Property Office on Jul. 21, 2011, the entire content of which is incorporated herein by reference.

### BACKGROUND

1. Field

Aspects of embodiments of the present invention relate to a solar cell module and a manufacturing method thereof.

2. Description of Related Art

Recently, as depletion of existing energy resources such as petroleum or coal has been predicted, alternative energy resources are gaining additional interest. Particularly, solar energy has attracted attention because it provides rich energy resources and does not cause, or causes less, environmental pollution.

As a photovoltaic element that converts solar energy to electric energy, a solar cell is gaining particular interest as an unlimited, or virtually unlimited, and non-polluting, or virtually non-polluting, next generation energy source.

Thus, a “building integrated photovoltaic” (BIPV) system using a solar cell as a finishing material of an external wall of a building has attracted attention.

Since the solar cell is attached to the external wall of the building in the BIPV system, natural lighting for light transmission becomes an important matter. That is, it is beneficial that the BIPV system produce electricity from solar energy and also allow natural light to be transmitted to the interior of the building.

The above information disclosed in this Background section is only for enhancement of understanding of the background of the invention and therefore it may contain information that does not form the prior art that is already known in this country to a person of ordinary skill in the art.

### SUMMARY

Embodiments of the present invention have been made in an effort to provide a solar cell module that allows for improved natural lighting and a manufacturing method thereof.

A manufacturing method of a solar cell module according to an exemplary embodiment of the present invention includes: forming a first electrode on a transparent substrate; forming a first groove at the first electrode by performing a first laser scribing process; forming a semiconductor layer on the first electrode; forming a second groove at the semiconductor layer by performing a second laser scribing process; forming a second electrode on the semiconductor layer; forming a third groove at the semiconductor layer and the second electrode by performing a third laser scribing process; and forming fourth and fifth grooves at the semiconductor layer and the second electrode by performing a fourth laser scribing process. The fourth laser scribing process includes using first and second laser beams.

The first groove, the second groove, and the third groove may be substantially parallel with each other, the fourth groove and the fifth groove may be substantially parallel with each other, and the fourth groove and the fifth groove may be substantially perpendicular to the third groove.

The fifth groove may include two fifth grooves, each of the fifth grooves being at a respective side of the fourth groove and a distance between the fourth groove and at least one of the fifth grooves may be in a range of 20 μm to 50 μm.

The width of the fourth groove may be in a range of 500 μm to 2 mm and the width of at least one of the fifth grooves may be in a range of 50 μm to 80 μm.

The fourth groove may be formed using the first laser beam, and the first laser beam may have a wave length of 1064±30 nm and a power in a range of 100 W to 1000 W.

The fifth groove may be formed using the second laser beam, and the second laser beam may have a wavelength of 532±30 nm and a power in a range of 0.1 W to 0.8 W.

The fourth laser scribing process may be further performed on the first electrode.

The fourth groove may be formed at the first electrode, the semiconductor layer, and the second electrode.

A manufacturing method of a solar cell module according to another exemplary embodiment of the present invention includes: forming a first electrode on a transparent substrate; forming a first groove at the first electrode by performing a first laser scribing process; forming a semiconductor layer on the first electrode; forming a second groove at the semiconductor layer by performing a second laser scribing process; forming a second electrode on the semiconductor layer; forming a third groove at the semiconductor layer and the second electrode by performing a third laser scribing process; and forming a fourth groove at the semiconductor layer and the second electrode by performing a fourth laser scribing process. For the fourth laser scribing process, a mask exposing a portion of the solar cell module where the fourth groove is formed is located under the transparent substrate and two laser generators and two beam machines are located at a position corresponding to the portion where the fourth groove is formed.

The first groove, the second groove, and the third groove may be substantially parallel with each other, and the fourth groove may be substantially perpendicular to the third groove.

The width of the fourth groove may be in a range of 500 μm to 2 mm.

The laser beams generated by the two laser generators may each have a wavelength of 532±30 nm.

A solar cell module according to another exemplary embodiment of the present invention includes: a transparent substrate; a first electrode on the transparent substrate and including a first groove; a semiconductor layer on the first electrode and including a second groove; and a second electrode on the semiconductor layer and including a third groove, a fourth groove, and a fifth groove. The third groove, the fourth groove, and the fifth groove are substantially parallel to the semiconductor layer, the first groove, the second groove, and the third groove are substantially parallel with each other, the fifth groove includes two fifth grooves, each of the fifth grooves being at a respective side of the fourth groove and substantially parallel with the fourth groove, and the fourth groove and the fifth grooves are substantially perpendicular to the third groove.

A distance between the fourth groove and at least one of the fifth grooves may be in a range of 20 μm to 50 μm.

The width of the fourth groove may be in a range of 500 μm to 2 mm and the width of at least one of the fifth grooves may be in a range of 50 μm to 80 μm.

The fourth groove may penetrate the first electrode.

As described, according to embodiments of the present invention, the fourth and fifth grooves are formed using two different laser beams so that natural lighting can be improved.

In addition, although the first and second electrodes are short-circuited in the fourth groove, the fifth groove insulates the first electrode and the second electrode from each other so that no problem is caused by the short-circuit.

### BRIEF DESCRIPTION OF THE DRAWINGS

FIG. 1 is a layout view of a solar cell module according to an exemplary embodiment of the present invention.

FIG. 2 is a cross-sectional view of FIG. 1, taken along the line II-II.

FIG. 3 is a cross-sectional view of FIG. 1, taken along the line III-III.

FIG. 4 to FIG. 10 are schematic views showing a manufacturing method of a solar cell module according to an exemplary embodiment of the present invention.

FIG. 11 is a schematic view showing a manufacturing method of a solar cell module according to another exemplary embodiment of the present invention.

FIG. 12 is a schematic view showing a manufacturing method of a solar cell module according to another exemplary embodiment of the present invention.

FIG. 13 is a schematic view showing a manufacturing method of a solar cell module according to another exemplary embodiment of the present invention.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. On the contrary, exemplary embodiments introduced herein are provided to make the disclosed contents thorough and complete, and to achieve a sufficient transfer of the spirit of the present invention to those skilled in the art.

In the drawings, the thickness of layers, films, panels, regions, etc., are exaggerated for clarity. It will be understood that when a layer is referred to as being “on” another layer or substrate, it can be directly on the other layer or substrate, or one or more other intervening layers or elements may also be present. Like reference numerals designate like elements throughout the specification.

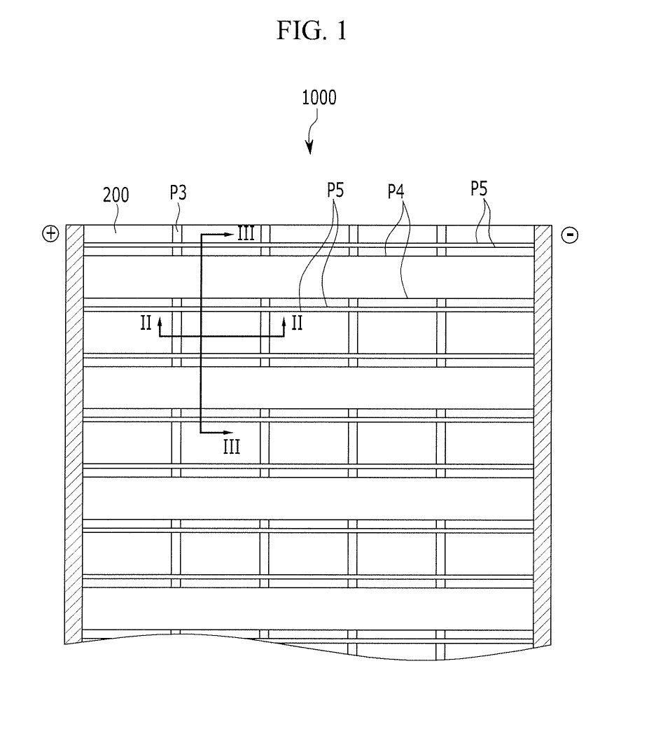

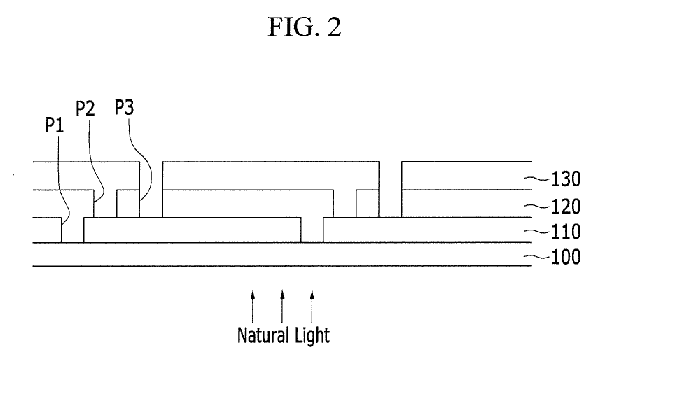

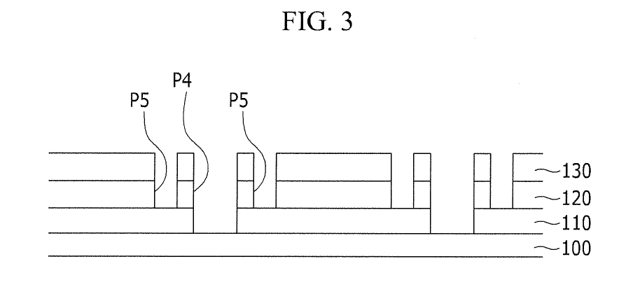

FIG. 1 is a layout view of a solar cell module according to an exemplary embodiment of the present invention, FIG. 2 is a cross-sectional view of FIG. 1, taken along the line II-II, and FIG. 3 is a cross-sectional view of FIG. 1, taken along the line III-III.

Referring to FIG. 1 to FIG. 3, a solar cell module 1000 includes a plurality of unit cells 200. Each cell 200 includes a first electrode 110, a second electrode 130, and a semiconductor layer 120 between the first and second electrodes 110 and 130. The solar cell module 1000 has a structure in which a second electrode 130 of one of neighboring unit cells 200 is connected with a first electrode 110 of the other of the neighboring unit cells 200.

As shown in FIG. 2, on a transparent substrate 100 made of glass or plastic, the first electrode 110 and a first groove P1 penetrating the first electrode 110 are formed.

The first electrode 110 may include a transparent electrode including at least one of boron doped ZnO (BZO:B), ((ZnO:B, Boron doped ZnO), tin oxide (SnO₂), indium tin oxide (ITO), or indium zinc oxide (IZO).

A semiconductor layer 120 filling the first groove P1 and a second groove P2 penetrating the semiconductor layer 120 are formed on the first electrode 110.

The semiconductor layer 120 is a portion that substantially generates electric energy, and may include a P layer including amorphous silicon doped with a P-type impurity, an I layer including intrinsic amorphous silicon, and an N layer including amorphous silicon doped with an N-type impurity.

The P layer, I layer and N layer may be double or triple layered. A material of the I layer may be amorphous silicon (a-Si), micro-crystal silicon (micro-crystal Si), amorphous silicon germanium (a-SiGe), micro-crystal silicon germanium (micro-crystal SiGe), and/or amorphous silicon carbide (a-SiC). The foregoing materials may be used individually, or they may be mixed.

On the semiconductor layer 120, a second electrode 130 filling the second groove P2 and a third groove P3 penetrating the second electrode 130 and the semiconductor layer 120 are formed.

The second electrode 130 may include a reflective electrode including silver (Ag), molybdenum (Mo), and/or nickel-vanadium (NiV) so as to prevent or reduce incident solar light from being emitted to the outside of the solar cell.

The first groove P1, the second groove P2 and the third groove P3 may be parallel or substantially parallel (i.e., are extended substantially in parallel) with each other.

The first groove P1 insulates the first electrode 110 and divides each cell 200 in the solar cell module 1000. The third groove P3 insulates neighboring unit cells 200 of the plurality of unit cells 200 in the solar cell module 1000. The second electrode 130 of a unit cell 200 is electrically connected to the first electrode 110 of a neighboring unit cell 200 through the second groove P2.

In addition, as shown in FIG. 3, a fourth groove P4 penetrates the first electrode 110, the semiconductor layer 120, and the second electrode 130. Fifth grooves P5 are formed at respective sides (e.g., opposing sides) of the fourth groove P4. That is, the fifth groove includes two fifth grooves, each of the fifth grooves being at a respective side of the fourth groove. The fifth groove or fifth grooves P5 penetrate the second electrode 130 and the semiconductor layer 120.

The fourth groove P4 and the fifth groove P5 may be parallel or substantially parallel (i.e., are extended substantially in parallel) with each other. In addition, the fourth groove P4 and the fifth groove P5 may be perpendicular or substantially perpendicular (i.e., are extended substantially perpendicularly) to the third groove.

In certain embodiments, the fourth groove P4 functions to transmit solar light, and the fifth groove P5 functions to insulate the first electrode 110 and the second electrode 130 from each other.

The width of the fourth groove P4 may be in a range of 500 μm to 2 mm and the width of the fifth groove (or at least one of the fifth grooves) P5 may be in a range of 50 μm to 80 μm. In addition, a distance between the fourth groove P4 and the fifth groove (or at least one of the fifth grooves) P5 may be in a range of 20 μm to 50 μm.

As described, in certain embodiments, the solar light is sufficiently transmitted through the fourth groove P4 such that natural lighting can be improved.

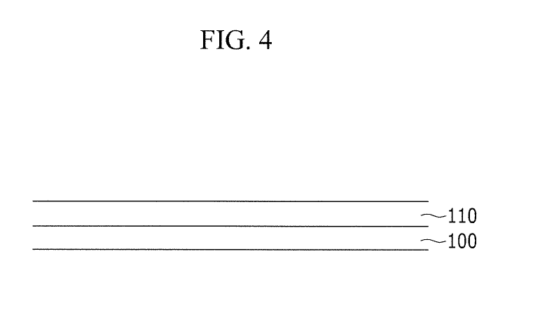

A manufacturing method of a solar cell module according to an exemplary embodiment of the present invention will now be described with reference to FIG. 4 to FIG. 10.

FIG. 4 to FIG. 10 show a manufacturing method of a solar cell module according to an exemplary embodiment of the present invention.

Referring to FIG. 4, a first electrode 110 is formed on a transparent substrate 100. The first electrode 110 may be formed using any suitable method, such as a chemical vapor deposition (CVD) method or a physical vapor deposition (PVD) method such as sputtering, but the present invention is not limited thereto.

The first electrode 110 may include a transparent electrode including at least one of boron doped ZnO (ZnO:B), tin oxide (SnO₂), indium tin oxide (ITO), or indium zinc oxide (IZO).

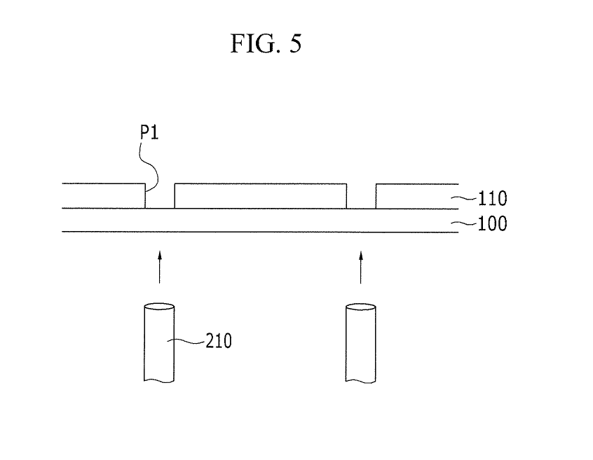

Referring to FIG. 5, a first laser scribing process is performed on the first electrode 110. For the first laser scribing process, first laser generators 210 for generating laser beams each having a wavelength of 1064±30 nm are located at the side of the transparent substrate 100. The laser beam generated by the first laser generator 210 is passed through the transparent substrate 100 and contacts (e.g., is applied to) the first electrode 110. Alternatively, the first laser generators 210 may be located at the side of the first electrode 110, and the laser beam generated by the first laser generator may contact the first electrode 110 without passing through the transparent substrate 100.

A plurality of first grooves P1 extended in one direction are formed in the first electrode 110 through the first laser scribing process using a laser beam having a power of 16 W. The first grooves P1 may be parallel or substantially parallel (i.e., are extended in parallel) with each other, and the transparent electrode 100 is exposed to bottom surfaces thereof (i.e., the transparent electrode 100 forms the bottom surfaces of the plurality of first grooves P1). The first electrode 110 is divided into a plurality of unit cells 200 by every two neighboring first grooves P1.

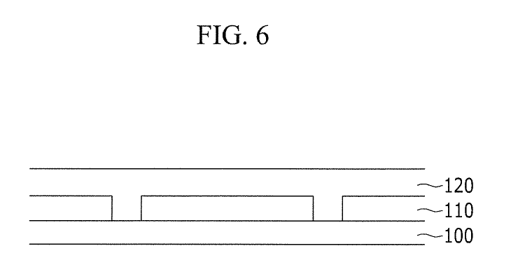

Referring to FIG. 6, a semiconductor layer 120 filling the first grooves P1 is formed on the first electrode 110. The semiconductor layer 120 is a portion that substantially generates electric energy using solar light, and may include a P layer including amorphous silicon doped with a P-type impurity, an I layer including intrinsic amorphous silicon, and an N layer including amorphous silicon doped with an N-type impurity.

The P layer, I layer and N layer may be double or triple layered. A material of the I layer may be amorphous silicon (a-Si), micro-crystal silicon (micro-crystal Si), amorphous silicon germanium (a-SiGe), micro-crystal silicon germanium (micro-crystal SiGe), and/or amorphous silicon carbide (a-SiC). The foregoing materials may be used individually, or they may be mixed.

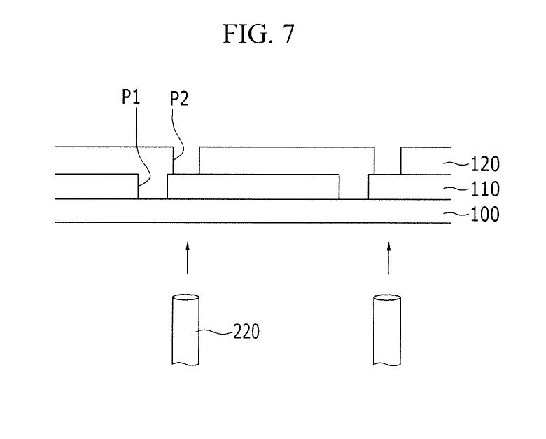

Referring to FIG. 7, a second laser scribing process is performed on the semiconductor layer 120. For the second laser scribing process, second laser generators 220 for generating laser beams each having a wavelength of 532±30 nm are located at the side of the transparent substrate 100, and the laser beam generated by the second laser generator 220 is passed through the transparent substrate 100 and the first electrode 110 and contacts (e.g., is applied to) the semiconductor layer 120. Alternatively, the second laser generators 220 may be located at the side of the semiconductor layer 120, and the laser beam generated by the second laser generator may contact the semiconductor layer 120 without passing through the transparent substrate 100 and the first electrode 110.

Using a laser beam having a power in a range of 0.3 W to 1 W, a second groove P2 is formed in the semiconductor layer 120 through the second laser scribing process. The second groove P2 is located several tens of micrometers from the first groove P1 and the first electrode 110 is exposed to the bottom surface of the second groove P2 (i.e., the first electrode 110 forms the bottom surface of the second groove P2).

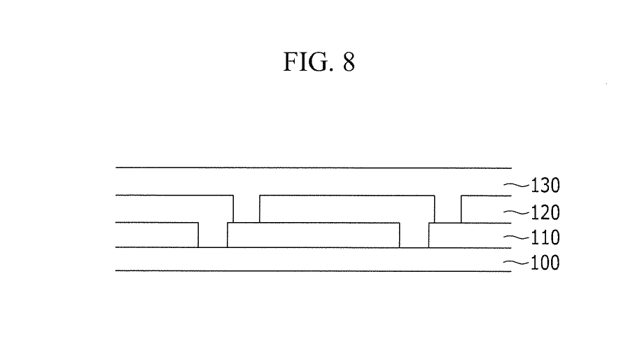

Referring to FIG. 8, a second electrode 130 filling the second groove P2 is formed on the semiconductor layer 120. The second electrode 130 may be formed using any suitable method, such as a chemical vapor deposition (CVD) method or a physical vapor deposition (PVD) method such as sputtering, but it is not limited thereto.

The second electrode 130 may include a reflective electrode including silver (Ag), molybdenum (Mo), and/or nickel-vanadium (NiV) to prevent or reduce incident solar light from being emitted to the outside of the solar cell.

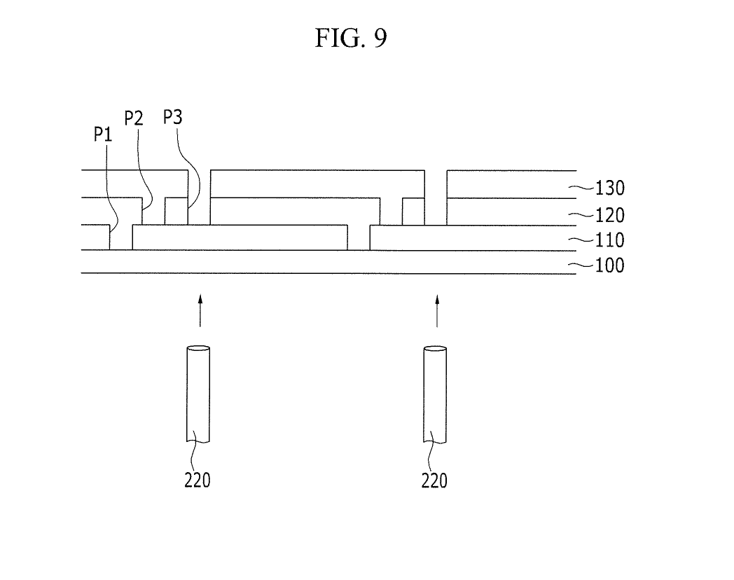

Referring to FIG. 9, a third laser scribing process is performed on the semiconductor layer 120 and the second electrode 130. For the third laser scribing process, the second laser generators 220 for generating laser beams each having a wavelength of 532±30 nm are located at the side of the transparent substrate 100. The laser beam generated by the second laser generator 220 is passed through the transparent substrate 100 and the first electrode 110 and contacts (e.g., is applied to) the semiconductor layer 120 and the second electrode 130. Alternatively, the second laser generators 220 may be located at the side of the second electrode 130, and the laser beam generated by the second laser generator may contact the semiconductor layer 120 and the second electrode 130 without passing through the transparent substrate 100 and the first electrode 110.

Using the laser beam having a power in a range of 0.3 W to 1 W, a third groove P3 is formed in the semiconductor layer 120 and the second electrode 130 through the third laser scribing process. The third groove P3 is located several tens of micrometers from the second groove P2 and the first electrode 110 is exposed to the bottom surface of the third groove P3 (i.e., the first electrode 110 forms the bottom surface of the third groove P3).

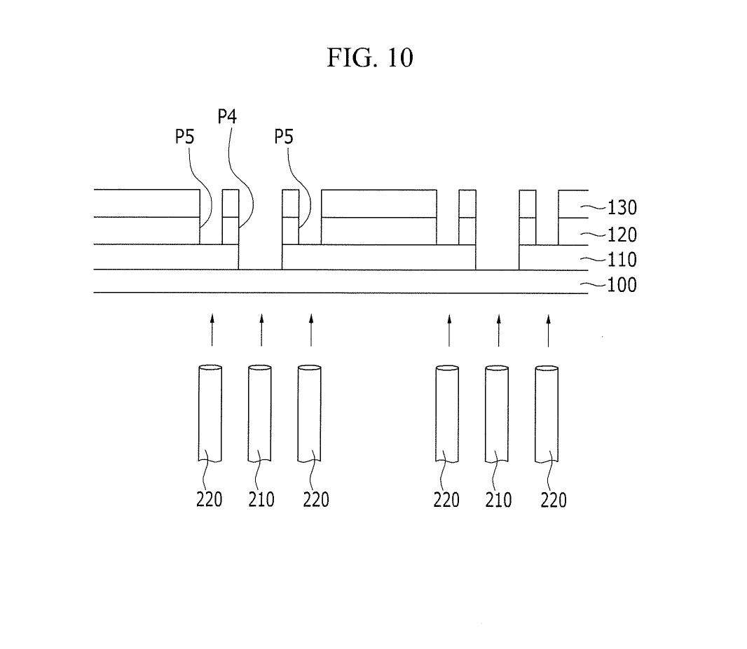

Referring to FIG. 10, a fourth laser scribing process is performed on the first electrode 110, the semiconductor layer 120, and the second electrode 130. For the fourth laser scribing process of this embodiment, the first laser generators 210 for generating laser beams each having a wavelength of 1064±30 nm and the second laser generators 220 for generating laser beams each having a wavelength of 532±30 nm, are located at the side of the transparent substrate 100. The second laser generators 220 are respectively located at two sides of the first laser generator 210.

The first laser generator 210 is located corresponding to a portion where a fourth groove P4 is formed, and the second laser generator 220 is located corresponding to a portion where a fifth groove P5 is formed.

The laser beam generated by the first laser generator 210 is passed through the transparent substrate 100 and contacts (e.g., is applied to) the first electrode 110, the semiconductor layer 120, and the second electrode 130, and the laser beam generated by the second laser generator 220 is passed through the transparent substrate 100 and the first electrode 110 and contacts (e.g., is applied to) the semiconductor layer 120 and the second electrode 130. Alternatively, the first laser generators 210 and the second laser generators 220 may be located at the side of the second electrode 130, and the laser beam generated by the first laser generator may contact the first electrode 110, the semiconductor layer 120, and the second electrode 130 without passing through the transparent substrate 100, and the laser beam generated by the second laser generator 220 may contact the semiconductor layer 120 and the second electrode 130 without passing through transparent substrate 100 and the first electrode 110.

The fourth grooves P4 are formed in the first electrode 110, the semiconductor layer 120, and the second electrode 130 through the fourth laser scribing process, and each of the fifth grooves P5 includes two fifth grooves, each of the fifth grooves being at a respective side (e.g., opposing sides) of the fourth groove P4. The transparent substrate 100 is exposed to the bottom surface of the fourth groove P4 (e.g., the transparent substrate forms the bottom surface of the fourth groove P4), the fifth grooves P5 are formed in the semiconductor layer 120 and the second electrode 130, and the first electrode is exposed to the bottom surface of the fifth groove P5 (e.g., the first electrode forms the bottom surface of the fifth groove P5).

The width of the fourth groove P4 may be in a range of 500 μm to 2 mm and the width of at least one of the fifth grooves P5 may be in a range of 50 μm to 80 μm. In addition, a distance between the fourth groove P4 and at least one of the fifth grooves P5 may be in a range of 20 μm to 50 μm.

The fourth grooves P4 are formed by laser beams generated by the first laser generators 210 each having a power in a range of 100 W to 1000 W, and the fifth grooves P5 are formed by laser beams generated by the second laser generators 220 each having a power in a range of 0.1 W to 0.8 W.

As described above, solar light is sufficiently transmitted by the fourth grooves P4 so that natural lighting can be improved. For example, solar light may be transmitted by the fourth groove P4 so that the amount of natural lighting received within a building may be increased. In addition, since the first electrode 110 and the second electrode 130 are insulated from each other by the fifth grooves P5 formed at respective sides (e.g., opposing sides) of the fourth groove P4, no problem may occur, or problems may be reduced, even though the first electrode 110 and the second electrode 130 are short-circuited when forming the fourth groove P4.

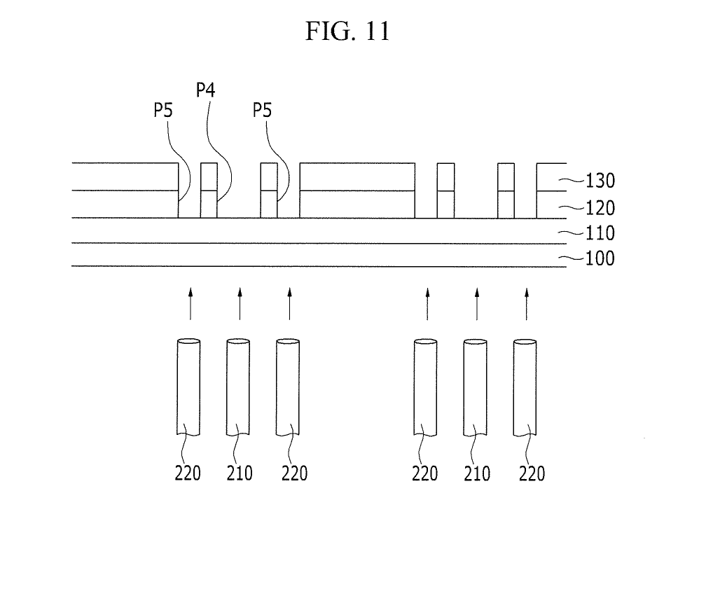

Alternatively, manufacturing methods of a solar cell module according to other exemplary embodiments of the present invention will be described in further detail with reference to FIG. 11 to FIG. 13.

FIG. 11 shows a manufacturing method of a solar cell module according to another exemplary embodiment of the present invention.

Referring to FIG. 11, the manufacturing method of the solar cell module of the present embodiment is the same as the manufacturing method described with reference to FIG. 4 to FIG. 10, except for the fourth laser scribing process, which is different from the process described in connection with FIG. 4 to FIG. 10.

According to this embodiment, a fourth scribing process is performed on a semiconductor layer 120 and a second electrode 130. For the fourth laser scribing process of this embodiment, first laser generators 210 for generating laser beams each having a wavelength of 1064±30 nm and second laser generators 220 for generating laser beams each having a wavelength of 532±30 nm, are located at the side of a transparent substrate 100, and the second laser generators 220 are located at two sides of the first laser generator 210.

The first laser generator 210 is located corresponding to a portion where the fourth groove P4 is formed, and the second laser generator 220 is located corresponding to a portion where the fifth groove P5 is formed.

The laser beams generated by the first laser generator 210 and the second laser generator 220 are passed through the transparent substrate 100 and a first electrode 110 and contact (e.g., are applied to) the semiconductor layer 120 and the second electrode 130. Alternatively, the first laser generators 210 and the second laser generators 220 may be located at the side of the second electrode 130, and the respective laser beams generated by the first laser generator and second laser generator may contact the semiconductor layer 120 and the second electrode 130 without passing through the transparent substrate 100 and the first electrode 110.

The fourth grooves P4 and the fifth grooves P5 are formed in the semiconductor layer 120 and the second electrode 130 through the fourth laser scribing process. The fifth grooves P5 includes two fifth grooves formed at respective sides of the fourth groove P4. The first electrode 110 is exposed to the bottom surfaces of the fourth and fifth grooves P4 and P5 (i.e., the first electrode 110 forms the bottoms surfaces of each of the fourth and fifth grooves P4 and P5).

The fourth grooves P4 are formed by laser beams generated by the first laser generators 210, and the fifth grooves P5 are formed by laser beams generated by the second laser generators 220. The laser beams generated by the first laser generators 210 each have a power in a range of 100 W to 1000 W, and the laser beams generated by the second laser generators 220 each have a power in a range of 0.1 W to 0.8 W.

The width of the fourth groove P4 may be in a range of 500 μm to 2 mm and the width of at least one of the fifth grooves P5 may be in a range of 50 μm to 80 μm. In addition, a distance between the fourth P4 and at least one of the fifth grooves P5 may be in a range of 20 μm to 50 μm.

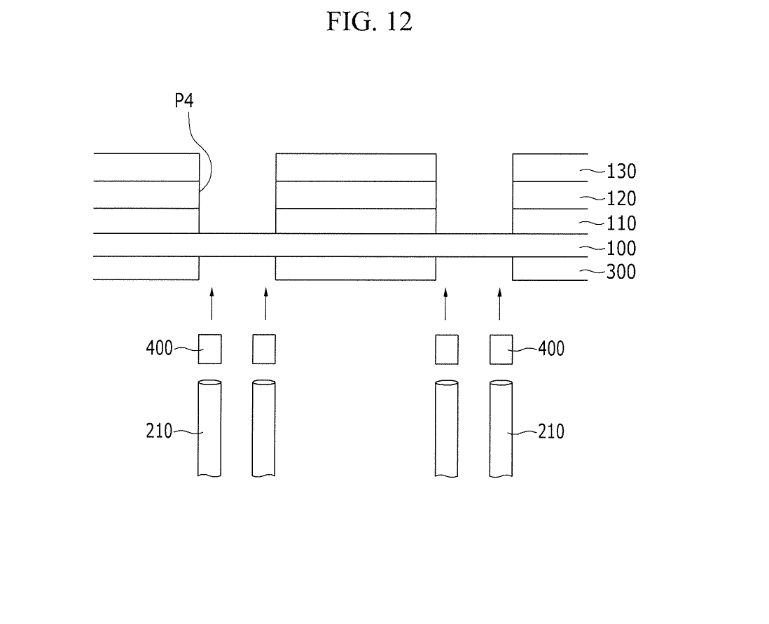

FIG. 12 shows a manufacturing method of a solar cell module according to another exemplary embodiment of the present invention.

Referring to FIG. 12, the manufacturing method of the present embodiment is the same as the manufacturing method of the solar cell module described with reference to FIG. 4 to FIG. 10, except for the fourth laser scribing process, which is different from the fourth laser scribing process described in connection with FIG. 4 to FIG. 10.

According to this embodiment, a fourth laser scribing process is performed on a first electrode 110, a semiconductor layer 120, and a second electrode 130. For the fourth laser scribing process of this embodiment, first laser generators 210 for generating laser beams each having a wavelength of 1064±30 nm are located at the side of a transparent substrate 100, and first beam machines 400 are located between the first laser generators 210 and the transparent substrate 100. The first beam machines 400 reduce the size (e.g., the diameter) of the laser beams generated by the first laser generators 210.

A mask 300 is located under a surface of the transparent substrate 100 where the first electrode 110 is not formed (i.e., under the surface of the transparent substrate 100 opposite the first electrode 110). A portion where a fourth groove is to be formed is exposed by the mask 300.

The laser beams generated by the first laser generators 210 are passed through the first beam machines 400 and the transparent substrate 100 and contact (e.g., are applied to) the first electrode 110, the semiconductor layer 120, and the second electrode 130. Alternatively, the first laser generators 210 and beam machines 400 may be located at the side of the second electrode 130, and the laser beams generated by the first laser generators 210 are passed through the first beam machines 400 and contact the first electrode 110, the semiconductor layer 120, and the second electrode 130 without passing through the transparent substrate 100.

Through the fourth laser scribing process of this embodiment, the fourth grooves P4 are formed in the first electrode 110, the semiconductor layer 120, and the second electrode 130. The transparent substrate 100 is exposed to the bottom portion of the fourth grooves P4 (i.e., the transparent substrate 100 forms the bottom surface of the fourth grooves P4). The width of the fourth groove P4 may be in a range of 500 μm to 2 mm.

The first beam machine 400 reduces the size (e.g., the diameter) of the laser beam generated by the first laser generator 210, and a mask 300 is formed under a portion of the transparent substrate 100, excluding a portion of the transparent substrate 100 corresponding to where the fourth groove P4 is formed, and therefore a failure or defect does not occur in a side surface of the fourth groove P4 by the laser beam generated by the first laser generator 210.

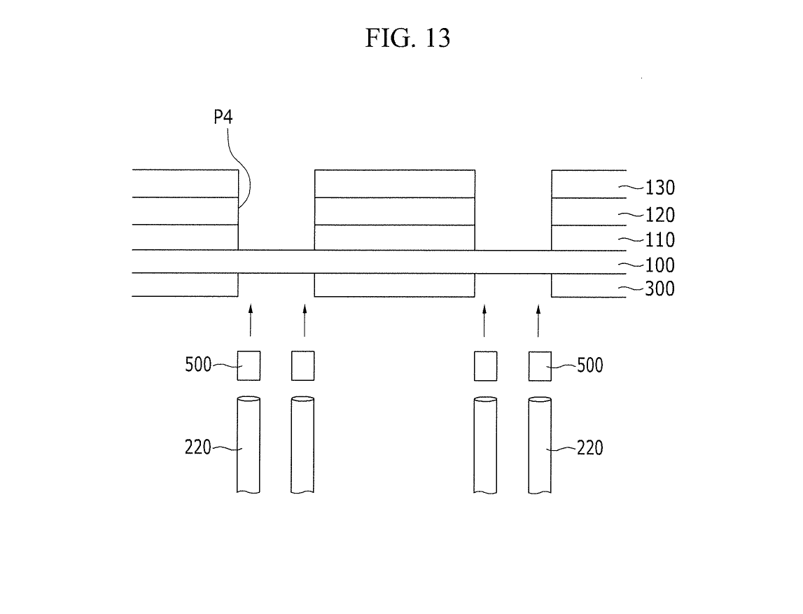

FIG. 13 shows a manufacturing method of a solar cell module according to another exemplary embodiment of the present invention.

The manufacturing method of FIG. 13 is the same as the manufacturing method of the solar cell module of FIG. 4 to FIG. 10, except for the fourth laser scribing process, which is different from the fourth laser scribing process described in connection with FIG. 4 to FIG. 10.

According to this embodiment, a fourth laser scribing process is performed on a first electrode 110, a semiconductor layer 120, and a second electrode 130. Here, for the fourth laser scribing process, second laser generators 220 for generating laser beams each having a wavelength of 532±30 are located at a side of a transparent substrate 100, and second beam machines 500 are each located between the respective second laser generators 220 and the transparent substrate 100. The second beam machine 500 reduces the size (e.g., the diameter) of the laser beam generated by the second laser generator 220.

A mask 300 is located under a surface of the transparent substrate 100 where a first electrode 110 is not formed (i.e., under the surface of the transparent substrate 100 opposite the first electrode 110). The mask 300 exposes a portion of the transparent substrate 100 corresponding to where the fourth groove P4 is to be formed.

The laser beam generated by the second laser generator 220 is passed through the second beam machine 500 and the transparent substrate 100 and then contacts (e.g., is applied to) the first electrode 110, the semiconductor layer 120, and the second electrode 130. Alternatively, the second laser generators 220 and the beam machines 500 may be located at the side of the second electrode 130, and the laser beam generated by the second laser generator 220 is passed through the second beam machine 500 and then contacts the first electrode 110, the semiconductor layer 120, and the second electrode 130 without passing through the transparent substrate 120.

Through the fourth laser scribing process of this embodiment, the fourth groove P4 is formed in the first electrode 110, the semiconductor layer 120, and the second electrode 130. The transparent substrate 100 is exposed to the fourth groove P4. The width of the fourth groove P4 may be in a range of 500 μm to 2 mm.

The second beam machine 500 reduces the size (e.g., the diameter) of the laser beam generated by the second laser generator 220, and the mask 300 is formed under a portion of the transparent substrate 100, excluding the portion of the transparent substrate corresponding to where the fourth groove P4 is formed, and therefore a failure or defect does not occur in a side surface of the fourth groove P4 formed by the laser beam generated by the second laser generator 220.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and their equivalents.

Description of some of the reference symbols

| | |
|---|---|
| 100: substrate | 110: first electrode |
| 120: semiconductor layer | 130: second electrode |
| 210: first laser generator | 220: second laser generator |
| P1: first groove | P2: second groove |
| P3: third groove | P4: fourth groove |
| P5: fifth groove | |

What is claimed is:

1. A manufacturing method of a solar cell module comprising:
forming a first electrode on a transparent substrate;
forming a first groove at the first electrode by performing a first laser scribing process;
forming a semiconductor layer on the first electrode;
forming a second groove at the semiconductor layer by performing a second laser scribing process;
forming a second electrode on the semiconductor layer;
forming a third groove at the semiconductor layer and the second electrode by performing a third laser scribing process; and
forming fourth and fifth grooves at the semiconductor layer and the second electrode by performing a fourth laser scribing process using first and second laser beams.

2. The manufacturing method of the solar cell module of claim 1, wherein the first groove, the second groove, and the third groove are substantially parallel with each other, the fourth groove and the fifth groove are substantially parallel with each other, and the fourth groove and the fifth groove are substantially perpendicular to the third groove.

3. The manufacturing method of the solar cell module of claim 2, wherein the fifth groove comprises two fifth grooves, each of the fifth grooves being at a respective side of the fourth groove and a distance between the fourth groove and at least one of the fifth grooves is in a range of 20 μm to 50 μm.

4. The manufacturing method of the solar cell module of claim 3, wherein the width of the fourth groove is in a range of 500 μm to 2 mm and the width of at least one of the fifth grooves is in a range of 50 μm to 80 μm.

5. The manufacturing method of the solar cell module of claim 4, wherein the fourth groove is formed using the first laser beam, and the first laser beam has a wavelength of 1064±30 nm and a power in a range of 100 W to 1000 W.

6. The manufacturing method of the solar cell module of claim 5, wherein the fifth groove is formed using the second laser beam, and the second laser beam has a wavelength of 532±30 nm and a power in a range of 0.1 W to 0.8 W.

7. The manufacturing method of the solar cell module of claim 6, wherein the fourth laser scribing process is further performed on the first electrode.

8. The manufacturing method of the solar cell module of claim 7, wherein the fourth groove is formed at the first electrode, the semiconductor layer, and the second electrode.

9. A manufacturing method of a solar cell module comprising:
forming a first electrode on a transparent substrate;
forming a first groove at the first electrode by performing a first laser scribing process;
forming a semiconductor layer on the first electrode;
forming a second groove at the semiconductor layer by performing a second laser scribing process;
forming a second electrode on the semiconductor layer;
forming a third groove at the semiconductor layer and the second electrode by performing a third laser scribing process; and
forming a fourth groove at the semiconductor layer and the second electrode by performing a fourth laser scribing process,
wherein, for the fourth laser scribing process,
a mask exposing a portion of the solar cell module where the fourth groove is formed is located under the transparent substrate, and two laser generators and two beam machines are located at a position corresponding to the portion where the fourth groove is formed.

10. The manufacturing method of the solar cell module of claim 9, wherein the first groove, the second groove, and the third groove are substantially parallel with each other, and the fourth groove is substantially perpendicular to the third groove.

11. The manufacturing method of the solar cell module of claim 10, wherein the width of the fourth groove is in a range of 500 μm to 2 mm.

12. The manufacturing method of the solar cell module of claim 11, wherein laser beams generated by the two laser generators each have a wavelength of 1064±30 nm.

13. The manufacturing method of the solar cell module of claim 11, wherein laser beams generated by the two laser generators each have a wavelength of 532±30 nm.

14. A solar cell module comprising:
a transparent substrate;
a first electrode on the transparent substrate and including a first groove;
a semiconductor layer on the first electrode and including a second groove; and
a second electrode on the semiconductor layer and including a third groove, a fourth groove, and a fifth groove,
wherein the third groove, the fourth groove, and the fifth groove are penetrate the semiconductor layer,
wherein the first groove, the second groove, and the third groove are substantially parallel with each other,
wherein the fifth groove comprises two fifth grooves, each of the fifth grooves being at a respective side of the fourth groove and substantially parallel with the fourth groove, and
wherein the fourth groove and the fifth grooves are substantially perpendicular to the third groove.

15. The solar cell module of claim 14, wherein a distance between the fourth groove and at least one of the fifth grooves is in a range of 20 μm to 50 μm.

16. The solar cell module of claim 14, wherein the width of the fourth groove is in a range of 500 μm to 2 mm and the width of at least one of the fifth grooves is in a range of 50 μm to 80 μm.

17. The solar cell module of claim 15, wherein the fourth groove penetrates the first electrode.
